(19) United States
(12) Patent Application Publication
(10) Pub. No.: US 2009/0139756 A1
(43) Pub. Date: Jun. 4, 2009

(54) FABRICATING PROCESS OF CIRCUIT BOARD WITH EMBEDDED PASSIVE COMPONENT

(75) Inventor: Ying-Ming Lee, Hsinchu (TW)

Correspondence Address: J C PATENTS, INC., 4 VENTURE, SUITE 250, IRVINE, CA, 92618, US

(73) Assignee: Subtron Technology Co. Ltd., Hsinchu (TW)

(21) Appl. No.: 12/168,274

(22) Filed: Jul. 7, 2008

(30) Foreign Application Priority Data
Dec. 3, 2007 (TW) 96145911

(51) Int. Cl. H05K 1/16; H05K 3/30

(52) U.S. Cl. 174/260; 29/832

(57) ABSTRACT

A fabricating process of a circuit board with an embedded passive component is described. First, a conductive layer including a first surface and a second surface opposite thereto is provided. The first surface has at least one component region on which at least one passive component material layer is formed. A passivation layer is formed on the first surface to cover the passive component material layer. A brown oxidation process is performed on the conductive layer. A circuit unit and an insulation layer are provided, and the insulation layer is set between the circuit unit and the conductive layer. The conductive layer, the circuit unit and the insulation layer are laminated. The passive component material layer is between the insulation layer and the conductive layer. The conductive layer is patterned to form a circuit layer.

### CROSS-REFERENCE TO RELATED APPLICATION

This application claims the priority benefit of Taiwan application serial no. 96145911, filed on Dec. 3, 2007. The entirety of the above-mentioned patent application is hereby incorporated by reference herein and made a part of this specification.

### BACKGROUND OF THE INVENTION

1. Field of the Invention

The present invention relates to a fabricating process of a circuit board, and in particular to a fabricating process of a circuit board with an embedded passive component.

2. Description of Related Art

As the integration of electronic products is increasingly improved, circuit layers of a circuit board applied to the high-integration electronic products increase from single layer, double layer to 6 layers, 8 layers and even more than 10 layers, so as to mount more electronic components on the printed circuit board. However, as the layer number of the circuit boards and the integration of circuits increase, the electrical signals transmitted in the circuit board cause more evident Resistance Capacitance delay or cross talk effect. In order to improve the electrical property of the circuit board, passive components must be mounted on a limited arrangement surface of the circuit board.

Accordingly, not only the passive components but also all kinds of electronic components must be mounted on the limited arrangement surface of the circuit board. However, a standardized passive component with specific electrical values may not completely fit to a special circuit design, embedding the passive component in the circuit board therefore becomes a feasible solution. In addition, the electrical values of the circuit board can be adjusted by the embedded passive component adopting different circuit layout designs and materials.

More specifically, the fabricating method of a circuit board having an embedded passive component usually includes forming a passive component material layer on a copper foil layer, and then a brown oxidation process is performed on the copper foil layer. Next, the copper foil layer and other circuit layers are laminated and then an etching process is performed on the copper foil layer to complete the fabricating process of the circuit board. It should be noted that the passive component material layer absorbs moisture induced by the brown oxidation process and thus the electrical quality is changed. As a result, the electrical quality of the final circuit board varies greatly.

### SUMMARY OF THE INVENTION

The present invention is directed to a fabricating process of a circuit board with an embedded passive component so as to reduce the influence on the electrical quality due to absorbed moisture induced by the brown oxidation process.

The present invention is directed to a circuit board with an embedded passive component, which has stable electrical quality.

The present invention provides a fabricating process of a circuit board with an embedded passive component, which includes the following steps: First, a conductive layer having a first surface and a second surface opposite thereto is provided, wherein the first surface has at least one component region. At least one passive component material layer is formed on the component region of the first surface. A passivation layer is formed on the first surface to cover the passive component material layer. A brown oxidation process is performed on the conductive layer and a plasma treatment is performed on the passivation layer. Then, a circuit unit and an insulation layer are provided, and the insulation layer is set between the circuit unit and the conductive layer, and the conductive layer, the circuit unit and the insulation layer are laminated, wherein the passive component material layer is set between the insulation layer and the conductive layer. The conductive layer is patterned to form a circuit layer.

According to one embodiment of the present invention, the fabricating process of the circuit board further includes performing a plasma treatment on the passive component material layer and the conductive layer before forming the passivation layer.

According to one embodiment of the present invention, the fabricating process of the circuit board includes forming a plurality of first through holes in the conductive layer before forming the passive component material layer and the circuit unit has a plurality of second through holes and the insulation layer has a plurality of third through holes. In the process of laminating the conductive layer, the circuit unit and the insulation layer, the conductive layer, the insulation layer and the circuit unit are aligned via the first, second and third through holes.

According to one embodiment of the present invention, the conductive layer is a copper foil layer.

According to one embodiment of the present invention, the method of forming a passivation layer includes screen printing.

According to one embodiment of the present invention, the passive component material layer covers a portion of the circuit layer, and the passive component material layer is made of an inductor material.

According to one embodiment of the present invention, the circuit layer further has a first electrode and a second electrode connected respectively to the passive component material layer, and the passive component material layer is made of a resistance material.

According to one embodiment of the present invention, the fabricating process of the circuit board further includes forming at least one electrode layer on the passive component material layer and the component region after forming the passive component material layer. The circuit layer further has a first electrode and a second electrode, wherein the first electrode is connected to the electrode layer and at least a portion of the electrode layer and at least a portion of the second electrode overlap, and the passive component material layer is made of a capacitance dielectric material.

According to one embodiment of the present invention, the method of forming the electrode layer includes screen printing.

According to one embodiment of the present invention, the insulation layer is made of prepreg.

The present invention provides a circuit board with an embedded passive component. The circuit board with the embedded passive component includes a circuit layer, a passive component material layer, a passivation layer, an insulation layer and a circuit unit, wherein the circuit layer has a first surface and a second surface opposite thereto, and the first surface has at least one component region. The passive component material layer is set on the component region of the circuit layer. The passivation layer is set on the first surface of the circuit layer, and covers the passive component material layer. The insulation layer is set on the circuit layer and covers the passive component material layer and the passivation layer. The circuit unit is set on the insulation layer.

According to one embodiment of the present invention, the passivation layer is made of epoxy resin.

According to one embodiment of the present invention, the passive component material layer covers a portion of the circuit layer, and the passive component material layer is made of an inductance material.

According to one embodiment of the present invention, the circuit layer further has a first electrode and a second electrode connected respectively to the passive component material layer, and the passive component material layer is made of a resistance material.

According to one embodiment of the present invention, the circuit board further includes an electrode layer covering the passive component material layer and a portion of the circuit layer. The passivation layer further covers the electrode layer and the circuit layer has a first electrode and a second electrode. The first electrode is connected to the electrode layer and the passive component material layer is set between the electrode layer and the second electrode. In addition, the passive component material layer is made of a capacitance dielectric material.

According to one embodiment of the present invention, the circuit unit is a multi-layered unit of a single-layered unit.

Based on the above, the present invention utilizes the passivation layer to cover the passive component material layer, and then the brown oxidation process is performed. Therefore, the moisture induced by the brown oxidation process does not enter the passive component material layer to affect the electrical quality.

In order to make the aforementioned and other objects, features and advantages of the present invention more comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1D are the schematic cross-sectional views illustrating a fabricating process of a circuit board with an embedded passive component according to the first embodiment of the present invention.

FIGS. 2A to 2D are the schematic cross-sectional views illustrating a fabricating process of a circuit board with an embedded passive component according to the second embodiment of the present invention.

### DESCRIPTION OF EMBODIMENTS

### The First Embodiment

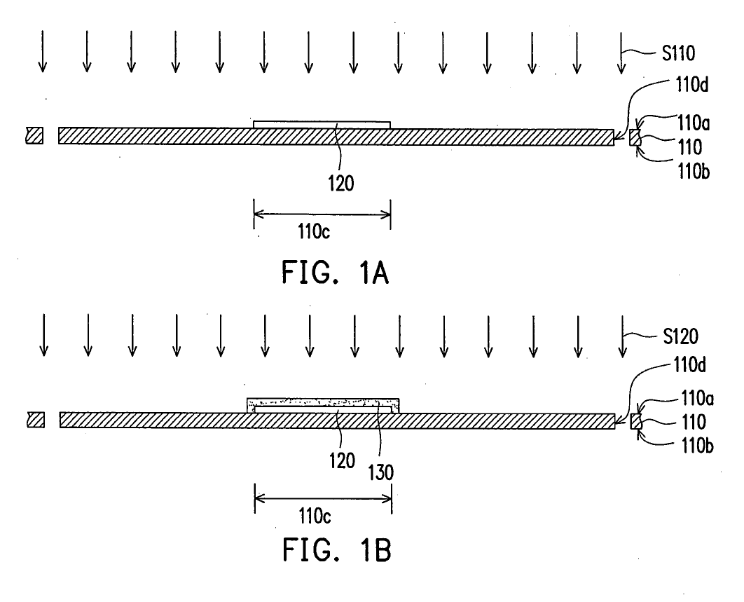

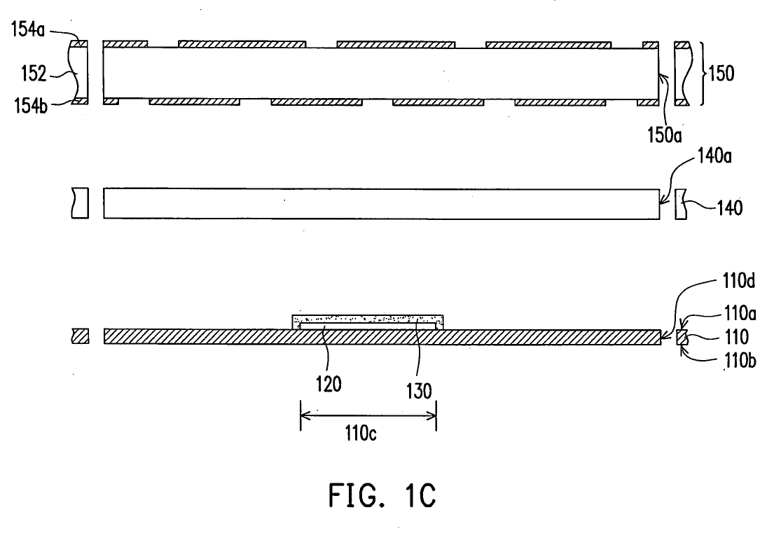

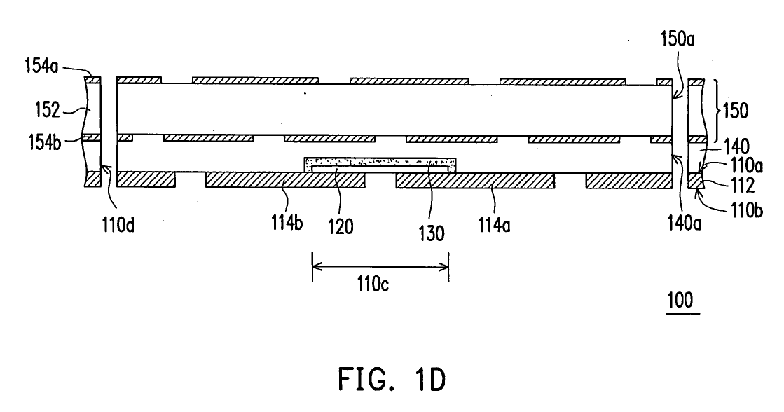

FIGS. 1A to 1D are the schematic cross-sectional views illustrating a fabricating process of a circuit board with an embedded passive component according to the first embodiment of the present invention. Referring to FIG. 1A, according to the present embodiment, the fabricating process of the circuit board with the embedded passive component includes the following steps: First, a conductive layer 110 is provided and the conductive layer 110 includes a first surface 110a and a second surface 110b opposite thereto, wherein the first surface 110a can have at least one component region 110c, and the conductive layer 110 can be a copper foil layer. In addition, according to the present embodiment, in order to facilitate the alignment of the conductive layer 110 in the following steps, the fabricating process of the circuit board can also include forming a plurality of first through holes 110d in the conductive layer 110, and a method of forming the first through holes 110d is, for example, performing a mechanical drill process or a laser drill process.

Then, please continue to refer to FIG. 1A, at least one passive component material layer 120 is formed on the component region 110c of the first surface 110a. In addition, a method of forming the passive component material layer 120 can be screen printing, and in the process of forming the passive component material layer 120, the first through holes 110d can also be used for alignment. According to the present embodiment, the passive component material layer 120 can be made of a resistance or an inductance material. However, when the passive component material layer 120 is made of a capacitance dielectric material, the fabricating process of the circuit board includes other steps following the formation of the passive component material layer 120. In addition, in order to enhance the bonding strength between the passive component material layer 120 and the later-formed passivation layer 130 (shown as in FIGS. 1A and 1B), a plasma treatment S110 can be applied to the conductive layer 110 and the passive component material layer 120 to enhance the roughness of the surface.

Referring to FIG. 1B, a passivation layer 130 is formed on the first surface 110a to cover the passive component material layer 120. In addition, the method of forming the passivation layer 130 can be screen printing. When a plasma treatment has been applied to the conductive layer 110 and the passive component material layer 120, the bonding strength between the passivation layer 130 and the conductive layer 110 or the passive component material layer 120 is stronger. Then, a curing process is performed to the passivation layer 130. Next, a brown oxidation process S120 and a plasma treatment S110 or a roughing process are performed on the conductive layer 110 and the passivation layer 130 respectively to enhance the roughness of the surfaces. It is worth noting that, because the passivation layer 130 which covers the passive component material layer 120, it is less likely for the moisture induced by the brown oxidation process to enter the passive component layer 120 and affects the electrical quality.

Referring to FIG. 1C, an insulation layer 140 and a circuit unit 150 are provided, wherein the insulation layer 140 can be made of prepreg and the circuit unit 150 can be multi-layered or single-layered unit. According to the present embodiment, the circuit unit 150 is a semi-product of a printed circuit board with multiple layers, and the circuit unit 150 includes a core layer 152 and circuit layers 154a and 154b which are set on two opposite surfaces of the core layer 152. In addition, the insulation layer 140 has a plurality of third through holes 140a, and the circuit unit 150 has a plurality of second through holes 150a.

Referring to FIGS. 1C and 1D, the insulation layer 140 is then set between the circuit unit 150 and the conductive layer 110, and the conductive layer 110, the circuit unit 150 and the insulation layer 140 are laminated together, wherein the passive component layer 120 is set between the insulation layer 140 and the conductive layer 110. When a plasma treatment has been applied to the passivation layer 130, the bonding strength between the insulation layer 140 and the passivation layer 130 is stronger. In addition, the conductive layer 110, the insulation layer 140 and the circuit unit 150 can be aligned via the first through holes 110d, the second through holes 150a and the third through holes 140a during the process of laminating the conductive layer 110 with the circuit unit 150 and the insulation layer 140.

Referring to FIG. 1D, the conductive layer 110 is patterned to form a circuit layer 112. Thereby, the fabricating process of the circuit board 100 with embedded passive component is substantially completed. In details, the method of patterning the conductive layer 110 includes a photolithography process and an etching process, wherein the photolithography process includes an exposure process and a development process. In addition, the circuit layer 112 has a first electrode 114a and a second electrode 114b which is electrically isolated from the first electrode 114a. The first electrode 114a and the second electrode 114b are respectively connected to the passive component material layer 120. When the passive component material layer 120 is made of the resistance material, the first electrode 114a, the second electrode 114b and the passive component material layer 120 constitute a resistance component. Likewise, when the passive component layer 120 is made of an inductance material, the first electrode 114a, the second electrode 114b and the passive component material layer 120 constitute an inductance component. The passive component material layer 120 covers a portion of the circuit layer 112. The structure of the circuit board 100 with the embedded component is described in detail hereinafter: Please continue referring to FIG. 1D, the circuit board 100 with the embedded passive component includes a circuit layer 112, a passive component material layer 120, a passivation layer 130, an insulation layer 140 and a circuit unit 150, wherein the circuit layer 112 has a first surface 110a and a second surface 110b opposite thereto, and the first surface 110a has at least one component region 110c. The passive component material layer 120 is set on the component region 110c of the circuit layer 112. The passivation layer 130 is set on the circuit layer 112 and covers the passive component material layer 120. The insulation layer 140 is set on the circuit layer 112, and covers the passive component material layer 120 and the passivation layer 130. The circuit unit 150 is set on the insulation layer 140.

In details, the circuit layer 112 has a first electrode 114a and a second electrode 114b which is electrically isolated from the first electrode 114a. The two electrodes are connected respectively to the passive component material layer 120, and the passive component material layer 120 can be made of a resistance or an inductance material. It is worth noting that, because the plasma treatment has been applied to the first surface 110a of the circuit layer 112 to enhance the roughness of the surface, the first surface 110a of the circuit layer 112 is rougher then a surface without plasma treatment. In addition, the passivation layer 130 can be made of epoxy resin or other materials which prevents moisture from entering the passive material layer 120. Because the passivation layer 130 can prevent moisture from getting into the passive component material layer 120, this circuit board 100 with the embedded passive component thus has a more stable electrical quality.

### Second Embodiment

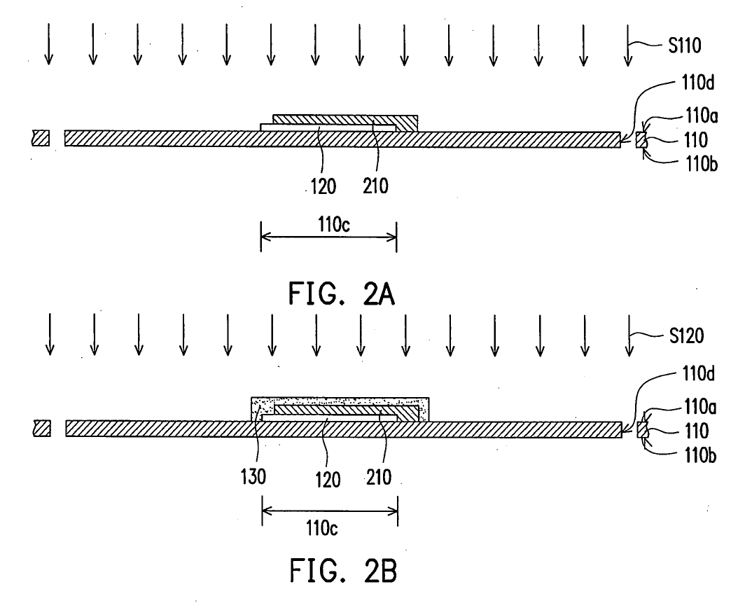

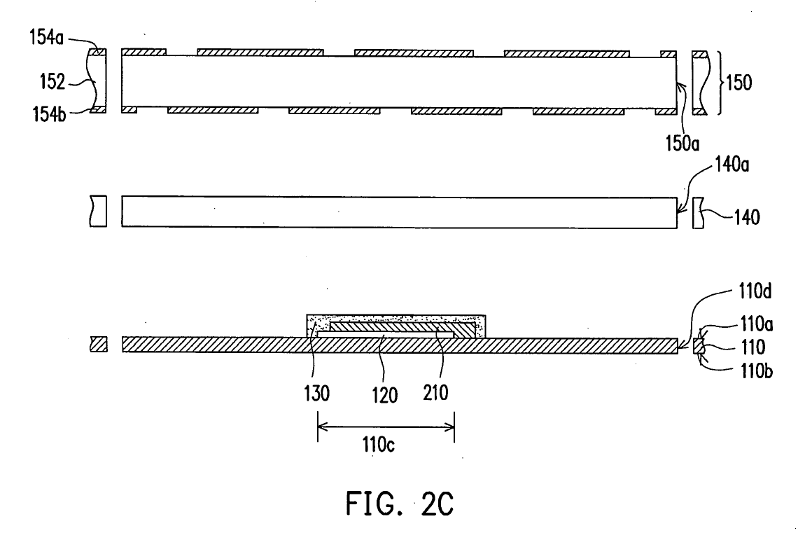

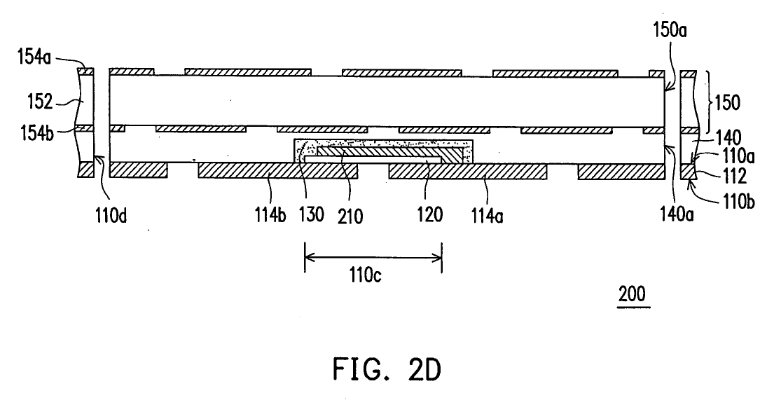

FIGS. 2A to 2D are the schematic cross-sectional views illustrating a fabricating process of a circuit board with an embedded passive component according to the second embodiment of the present invention. Referring to FIG. 2A, the present embodiment is similar to the first embodiment with the difference lying in that the present embodiment of the fabricating process of the circuit board with the embedded passive component includes forming at least one electrode layer 210 on the passive component material layer 120 and the component region 110c after forming the passive component material 120. In addition, the electrode layer 210 can be made of copper paste, and the method of forming the electrode layer 210 can be screen printing. Then, a curing process is performed to cure the electrode layer 210. Then, as in the first embodiment, a plasma treatment S110 is performed to the conductive layer 110, the passive component material layer 120 and the electrode layer 210 in order to enhance the roughness of the surfaces.

Referring to FIG. 2B, a passivation layer 130 is formed on the conductive layer 110 to cover the passive component material layer 120 and the electrode layer 210. Likewise, when a plasma treatment has been applied to the electrode layer 210, the conductive layer 110 and the passive component material layer 120, the bonding strength between the passivation layer 130 and the conductive layer 110 or the passive component material layer 120 or the electrode layer 210 is stronger. Then, a brown oxidation process S120 and a plasma treatment S110 or a roughing process are performed respectively on the conductive layer 110 and the passivation layer 130 to enhance the roughness of the surface. It is worth noting that, thanks to the passivation layer 130 which covers the passive component material layer 120, it is less likely for the moisture induced by the brown oxidation process to enter the passive component layer 120 and affects the electrical quality.

Referring to FIGS. 2C and 2D, the conductive layer 110, the circuit unit 150 and the insulation layer 140 are laminated, wherein the passive component material layer 120 is set between the insulation layer 140 and the conductive layer 110. When a plasma treatment has been applied to the passivation layer 130, the bonding strength between the insulation layer 140 and the passivation layer 130 is stronger. In addition, during the process of laminating the conductive layer 110, the circuit unit 150 and the insulation layer 140, the conductive layer 110, the insulation layer 140 and the circuit unit 150 can be aligned via the first through holes 110d, the second through holes 150a and the third through holes 140a.

Referring to FIG. 2D, the conductive layer 110 is patterned to form a circuit layer 112. Thereby, the fabricating process of the circuit board 200 with the embedded passive component is substantially completed. In addition, the circuit layer 112 has a first electrode 114a and a second electrode 114b, wherein the first electrode 114a is connected to the electrode layer 210, and at least a portion of the electrode layer 210 and at least a part of the second electrode 114b overlap, and the passive component material layer 120 is made of a capacitance dielectric material. In other words, the electrode layer 210, the first electrode 114a, the second electrode 114b and the passive component material layer 120 can constitute a capacitance component.

In summary, the present invention of the fabricating process of the circuit board with the embedded passive component has the following advantages:

First, compared to a conventional art wherein the passive component material layer is easily affected by the moisture induced during the brown oxidation process, the present invention applies a passivation layer to cover the passive component material layer and thus the passive component material layer is less likely to be affected by moisture. In other words, the circuit board with the embedded passive component according to the present invention has more stable electrical quality.

Second, according to the present invention, in the fabricating process of the circuit board with the embedded passive component, the embedded resistance component, inductance component or capacitance component can be formed more easily so as to fit to the layout of the circuit.

Third, according to the present invention, the fabricating process of the circuit board with the embedded passive component is compatible with currently used equipments and no additional equipment is required.

Forth, roughing the surfaces of the passivation layer, the electrode layer and the passive component material layer with a plasma treatment effectively enhances the bonding strength.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabricating process of a circuit board with an embedded passive component, comprising:
providing a conductive layer with a first surface and a second surface opposite thereto, the first surface having at least one component region;
forming at least one passive component material layer on the component region of the first surface;
forming a passivation layer on the first surface to cover the passive component material layer;
performing a brown oxidation process on the conductive layer and applying a plasma treatment to the passivation layer;
providing a circuit unit and an insulation layer, and setting the insulation layer between the circuit unit and the conductive layer, and then laminating the conductive layer, the circuit unit and the insulation layer, wherein the passive component material layer is set between the insulation layer and the conductive layer; and
patterning the conductive layer to form a circuit layer.

2. The fabricating process of the circuit board with the embedded passive component according to claim 1, further comprising performing a plasma treatment to the passive component material layer and the conductive layer before forming the passivation layer.

3. The fabricating process of the circuit board with the embedded component according to claim 1, further comprising forming a plurality of first though holes in the conductive layer before forming the passive component material layer, wherein the circuit unit has a plurality of second through holes, the insulation layer has a plurality of third through holes, and the conductive layer, the insulation unit and the circuit unit are aligned via the first through holes, the second through holes and the third through holes during the process of laminating the conductive layer, the circuit unit and the insulation layer.

4. The fabricating process of the circuit board with the embedded passive component according to claim 1, wherein the conductive layer is a copper foil layer.

5. The fabricating process of the circuit board with the embedded passive component according to claim 1, wherein a method of forming the passivation layer includes screen printing.

6. The fabricating process of the circuit board with the embedded passive component according to claim 1, wherein the passive component material layer covers a portion of the circuit layer and the passive component material layer comprises an inductance material.

7. The fabricating process of the circuit board with the embedded passive component according to claim 1, wherein the circuit layer further has a first electrode and a second electrode connected respectively to the passive component material layer, and the passive component material layer comprises a resistance material.

8. The fabricating process of the circuit board with the embedded passive component according to claim 1, further comprising forming an electrode layer on the passive component material layer and the component region, wherein the circuit layer has a first electrode and a second electrode, the first electrode is connected to the electrode layer, at least a portion of the electrode layer and at least a portion of the second electrode overlap each other and the passive component material layer comprises a capacitance dielectric material.

9. The fabricating process of the circuit board with the embedded passive component according to claim 8, wherein the method of forming the passivation layer includes screen printing.

10. The fabricating process of the circuit board with the embedded passive component according to claim 1, wherein the conductive layer is made of prepreg.

11. A circuit board with an embedded passive component, comprising:
a circuit layer having a first surface and a second surface opposite thereto, and the first surface having at least one component region;
a passive component material layer, set on the component region of the circuit layer;
a passivation layer, set on the first surface of the circuit layer and covering the passive component material layer;
an insulation layer, set on the circuit layer and covering the passive component material layer and the passivation layer; and
a circuit unit, set on the insulation layer.

12. The circuit board with the embedded passive component according to claim 11, wherein the passivation layer comprises epoxy resin.

13. The circuit board with the embedded passive component according to claim 11, wherein the passive component material layer covers a portion of the circuit layer, and the passive component material layer comprises an inducance material.

14. The circuit board with the embedded passive component according to claim 11, wherein the circuit layer has a first electrode and a second electrode respectively connected to the passive component material layer, and the passive component material layer comprises a resistance material.

15. The circuit board with the embedded passive component according to claim 11, further comprising an electrode layer covering the passive component material layer and a portion of the circuit layer and the passivation layer covering the electrode layer, the circuit layer having a first electrode and a second electrode, wherein the first electrode is connected to the electrode layer, and the passive component material layer is set between the electrode layer and the second electrode, and the passive component material layer comprises a capacitance dielectric material.

16. The circuit board with the embedded passive component according to claim 11, wherein the circuit unit is a multi-layered or a single-layered unit.
